(19) United States
(12) Patent Application Publication
(10) Pub. No.: US 2024/0357944 A1
(43) Pub. Date: Oct. 24, 2024

(54) RAW MATERIAL SOLUTION FOR MANUFACTURING OXIDE SUPERCONDUCTING MATERIAL AND METHOD FOR MANUFACTURING OXIDE SUPERCONDUCTING MATERIAL

(71) Applicant: SUMITOMO ELECTRIC INDUSTRIES, LTD., Osaka (JP)

(72) Inventors: Genki HONDA, Osaka (JP); Tatsuoki NAGAISHI, Osaka (JP); Iwao YAMAGUCHI, Tsukuba-shi, Ibaraki (JP); Takaaki MANABE, Tsukuba-shi, Ibaraki (JP); Hiroaki MATSUI, Tsukuba-shi, Ibaraki (JP)

(73) Assignee: SUMITOMO ELECTRIC INDUSTRIES, LTD., Osaka (JP)

(21) Appl. No.: 18/682,896

(22) PCT Filed: Sep. 1, 2022
(86) PCT No.: PCT/JP2022/033003

§ 371 Date: Feb. 10, 2024

(30) Foreign Application Priority Data
Sep. 6, 2021 (JP) 2021-144693

(51) Int. Cl. H10N 60/01; C01G 3/00; C09D 1/00; C09D 5/24

(52) U.S. Cl. CPC H10N 60/0464; C01G 3/00; C09D 1/00; C09D 5/24; C01P 2006/40

(57) ABSTRACT

A raw material solution contains a rare earth element carboxylate having 1 or more and 4 or less carbon atoms, a barium carboxylate having 1 or more and 4 or less carbon atoms, and a copper carboxylate having 1 or more and 4 or less carbon atoms, as solutes, and water, two or more types of alcohols having 1 or more and 4 or less carbon atoms, a carboxylic acid having 1 or more and 4 or less carbon atoms, and a basic organic solvent, as solvents. A method for manufacturing an oxide superconducting material comprises a step of preparing a raw material solution, a step of forming a coating film from the raw material solution, a step of heating the coating film to form a calcined film, and a step of heating the calcined film to form an oxide superconducting material.

### TECHNICAL FIELD

The present disclosure relates to a raw material solution for manufacturing an oxide superconducting material and a method for manufacturing an oxide superconducting material. The present application claims priority based on Japanese Patent Application No. 2021-144693 filed on Sep. 6, 2021. The contents described in the Japanese Patent Application are incorporated herein by reference in its entirety.

### BACKGROUND ART

As one manufacturing method for manufacturing an oxide superconducting

material, there is a method called metal organic decomposition method (abbreviated as MOD method). This method is a method for manufacturing a superconducting material in which a raw material solution (hereinafter, also referred to as “MOD solution”) manufactured by dissolving an organometallic compound in a solvent is applied to a substrate, then subjected to heat treatment (hereinafter, also referred to as calcination) at around 500° C., and thermally decomposed, and the obtained thermally decomposed product (hereinafter, also referred to as “calcined film”) is subjected to heat treatment (hereinafter, also referred to as firing) at a further high temperature (e.g., around 800° C.) and crystallized. The MOD method has such characteristics that manufacturing equipment is easy as compared with gas phase methods (such as a vapor deposition method, a spattering method, and a pulse laser deposition method) by which manufacturing is mainly carried out in a vacuum, and it is easy to cope with a large area and a complicate shape, and the like.

Regarding the above MOD method, NPL 1 (Mizuta et.al., “Preparation of Superconducting Films by Dipping-Pyrolysis Process”, Journal of The Chemical Society of Japan, 1997, No. 1, p. 11-23) discloses using a raw material solution obtained by dissolving each organometallic compound of a rare earth element, barium, and copper in a mixed solvent in which the ratio of pyridine to propionic acid is 5:3, evaporating the mixture to dryness, and then further dissolving the resulting product in methanol.

PTL 1 (Japanese Patent Laying-Open No. 2012-12247) discloses using a raw material solution obtained by dissolving the evaporated and dried product obtained in the manner described in NPL 1 in a mixed solvent of methanol, 1-butanol, and water, instead of methanol. Further, PTL 2 (Japanese Patent Laying-Open No. 2011-253764) discloses using a raw material solution in which hydrochloric acid is added as a chlorine source, and each of PTL 3 (Japanese Patent Laying-Open No. 2013-122847) and PTL 4 (Japanese Patent Laying-Open No. 2015-165502) discloses using a raw material solution in which ammonium chloride is added as a chlorine source. In addition, PTL 5 (WO 2018/163501) discloses the structure and properties of an oxide superconducting material manufactured by a metal organic decomposition method in which the above raw material solution is used.

### CITATION LIST

### Patent Literature

PTL 1: Japanese Patent Laying-Open No. 2012-12247

PTL 2: Japanese Patent Laying-Open No. 2011-253764

PTL 3: Japanese Patent Laying-Open No. 2013-122847

PTL 4: Japanese Patent Laying-Open No. 2015-165502

PTL 5: WO2018/163501

### Non Patent Literature

NPL 1: Mizuta et.al., “Preparation of Superconducting Films by Dipping-Pyrolysis Process”, Journal of The Chemical Society of Japan, 1997, No. 1, p. 11-23

### SUMMARY OF INVENTION

The raw material solution according to one aspect of the present disclosure is a raw material solution used in manufacture of an oxide superconducting material using a metal organic decomposition method. Such a raw material solution contains a rare earth element carboxylate having 1 or more and 4 or less carbon atoms, a barium carboxylate having 1 or more and 4 or less carbon atoms, and a copper carboxylate having 1 or more and 4 or less carbon atoms, as solutes, and water, two or more types of alcohols having 1 or more and 4 or less carbon atoms, a carboxylic acid having 1 or more and 4 or less carbon atoms, and a basic organic solvent, as solvents.

The method for manufacturing an oxide superconducting material according to one aspect of the present disclosure comprises a step of preparing the raw material solution of the above aspect, a step of applying the raw material solution on a substrate and drying to form a coating film, a step of heating the coating film, thermally decomposing the above rare earth element carboxylate, the above barium carboxylate, and the above copper carboxylate in the coating film, and removing organic components to form a calcined film, and a step of heating and crystallizing the calcined film to form an oxide superconducting material.

### BRIEF DESCRIPTION OF DRAWING

FIG. 1 is a flow chart illustrating one example of a method for manufacturing an oxide superconducting material according to one aspect of the present disclosure.

### DETAILED DESCRIPTION

### [Problem to be Solved by the Present Disclosure]

However, conventional raw material solutions used in the metal organic decomposition methods disclosed in NPL 1 and PTL 1 to 5 require multiple steps of a first dissolution step of dissolving each organometallic compound of a rare earth element, barium, and copper in a pyridine-propionic acid mixed solvent (hereinafter, also referred to as the first solvent), as described above, an evaporation drying step of the first solution obtained in the first dissolution step, and a second dissolution step of dissolving the evaporated and dried product in a solvent containing methanol (hereinafter, also referred to as the second solvent). In addition, when the first solvent is completely evaporated in the evaporation drying step, crystals are easily precipitated after the second dissolution step, and thus the amount of the first solvent to be evaporated is required to be precisely controlled.

Thus, an object of the present disclosure is to provide a raw material solution that requires neither multiple steps nor precise control upon preparation of the raw material solution and can be efficiently manufactured. In addition, an object of the present disclosure is to provide a method for manufacturing an oxide superconducting material that enables a high-quality oxide superconducting material to be efficiently manufactured using such a raw material solution.

### [Advantageous Effect of the Present Disclosure]

According to the present disclosure, a raw material solution that requires neither multiple steps nor precise control upon preparation of the raw material solution and can be efficiently manufactured can be provided. In addition, according to the present disclosure, a method for manufacturing an oxide superconducting material that enables a high-quality oxide superconducting material to be efficiently manufactured using such a raw material solution can be provided.

### [Description of Embodiments]

Hereinafter, the embodiments of the present disclosure will be first listed and described.

[1] The raw material solution according to one embodiment of the present disclosure is a raw material solution used in manufacture of an oxide superconducting material using a metal organic decomposition method. Such a raw material solution contains a rare earth element carboxylate having 1 or more and 4 or less carbon atoms, a barium carboxylate having 1 or more and 4 or less carbon atoms, and a copper carboxylate having 1 or more and 4 or less carbon atoms, as solutes, and water, two or more types of alcohols having 1 or more and 4 or less carbon atoms, a carboxylic acid having 1 or more and 4 or less carbon atoms, and a basic organic solvent, as solvents. The raw material solution of the present embodiment does not require evaporation drying upon its preparation, and has high solubility of the solute, dissolution stability, and wettability on the substrate. Thus, such a raw material solution requires neither multiple steps nor precise control upon preparation, can be efficiently manufactured, and enables a high-quality oxide superconducting material to be efficiently manufactured.

[2] In the raw material solution, at least one carboxylate of the rare earth element carboxylate, the barium carboxylate, and the copper carboxylate may be a monocarboxylate having 2 or more and 3 or less carbon atoms. Such a raw material solution does not require evaporation drying upon its preparation, and has high solubility of the solute, dissolution stability, and wettability on the substrate. Thus, such a raw material solution requires neither multiple steps nor precise control upon preparation, can be efficiently manufactured, and enables a high-quality oxide superconducting material to be efficiently manufactured.

[3] In the raw material solution, at least one carboxylate of the rare earth element carboxylate, the barium carboxylate, and the copper carboxylate may be a dicarboxylate having 2 or more and 4 or less carbon atoms. Such a raw material solution does not require evaporation drying upon its preparation, and has high solubility of the solute, dissolution stability, and wettability on the substrate. Thus, such a raw material solution requires neither multiple steps nor precise control upon preparation, can be efficiently manufactured, and enables a high-quality oxide superconducting material to be efficiently manufactured.

[4] In the raw material solution, the alcohol may contain an alcohol having 1 or more and 2 or less carbon atoms and an alcohol having 3 or more and 4 or less carbon atoms. Such a raw material solution does not require evaporation drying upon its preparation, and has high solubility of the solute, dissolution stability, and wettability on the substrate. Thus, such a raw material solution requires neither multiple steps nor precise control upon preparation, can be efficiently manufactured, and enables a high-quality oxide superconducting material to be efficiently manufactured.

[5] In the raw material solution, the volume ratio of the alcohol having 1 or more and 2 or less carbon atoms to the alcohol having 3 or more and 4 or less carbon atoms may be in the range of 5:1 to 1:5. Such a raw material solution does not require evaporation drying upon its preparation, and has well-balanced and high solubility of the solute, dissolution stability, and wettability on the substrate. Thus, such a raw material solution requires neither multiple steps nor precise control upon preparation and can be further efficiently manufactured, and enables a high-quality oxide superconducting material to be further efficiently manufactured.

[6] In the raw material solution, the carboxylic acid may be a monocarboxylic acid having 2 or more and 3 or less carbon atoms. Such a raw material solution does not require evaporation drying upon its preparation, and has high solubility of the solute, dissolution stability, and wettability on the substrate. Thus, such a raw material solution requires neither multiple steps nor precise control upon preparation, can be efficiently manufactured, and enables a high-quality oxide superconducting material to be efficiently manufactured.

[7] In the raw material solution, the basic organic solvent may be an organic compound containing a nitrogen atom. Such a raw material solution does not require evaporation drying upon its preparation, and has high solubility of the solute, dissolution stability, and wettability on the substrate. Thus, such a raw material solution requires neither multiple steps nor precise control upon preparation, can be efficiently manufactured, and enables a high-quality oxide superconducting material to be efficiently manufactured.

[8] In the raw material solution, the solvent may have a content of the water of 10% by volume or more and 30% by volume or less, a content of the alcohol of 20% by volume or more and 80% by volume or less, a total content of the carboxylic acid and the basic organic solvent of 10% by volume or more and 50% by volume or less. Such a raw material solution does not require evaporation drying upon its preparation, and has well-balanced and high solubility of the solute, dissolution stability, and wettability on the substrate. Thus, such a raw material solution requires neither multiple steps nor precise control upon preparation, can be efficiently manufactured, and enables a high-quality oxide superconducting material to be efficiently manufactured.

[9] A method for manufacturing an oxide superconducting material according to one embodiment of the present disclosure comprises a step of preparing the raw material solution, a step of applying the raw material solution on a substrate and drying to form a coating film, a step of heating the coating film, thermally decomposing the rare earth element carboxylate, the barium carboxylate, and the copper carboxylate in the coating film, and removing organic components to form a calcined film, and a step of heating and crystallizing the calcined film to form an oxide superconducting material. Since the method for manufacturing an oxide superconducting material of the present embodiment uses the raw material solution, the method enables a high-quality oxide superconducting material to be efficiently manufactured.

The method for manufacturing an oxide superconducting material may further comprise a step of filtering the raw material solution after the step of preparing the raw material solution and before the step of forming a coating film. Such a method for manufacturing an oxide superconducting material enables a further high-quality oxide superconducting material to be efficiently manufactured by removing insoluble impurities in the raw material solution.

### [Detail of Embodiment of the Present Disclosure]

### <Embodiment 1: Raw Material Solution>

The raw material solution of the present embodiment is a raw material solution used in manufacture of an oxide superconducting material using a metal organic decomposition method, wherein the raw material solution contains a rare earth element carboxylate having 1 or more and 4 or less carbon atoms (hereinafter, also referred to as the RE carboxylate), a barium carboxylate having 1 or more and 4 or less carbon atoms (hereinafter, also referred to as the Ba carboxylate), and a copper carboxylate having 1 or more and 4 or less carbon atoms (hereinafter, also referred to as Cu carboxylate) as solutes, and water, two or more types of alcohols having 1 or more and 4 or less carbon atoms, a carboxylic acid having 1 or more and 4 or less carbon atoms, and a basic organic solvent, as solvents. The raw material solution of the present embodiment does not require evaporation drying upon its preparation, and has high solubility of the solute, dissolution stability, and wettability on the substrate. Thus, the raw material solution of the present embodiment requires neither multiple steps nor precise control upon preparation, can be efficiently manufactured, and enables a high-quality oxide superconducting material to be efficiently manufactured.

As described above, conventional raw material solutions used in NPL 1 and PTL 1 to 5 require multiple steps of the first dissolution step, the evaporation drying step, and the second dissolution step. In addition, when the first solvent is completely evaporated in the evaporation drying step, crystals are easily precipitated after the second dissolution step, so that the amount of the first solvent to be evaporated is required to be precisely controlled.

Here, in evaporation drying in the manufacture of the conventional raw material solutions used in PTL 1 to 5, the solvent removed by distillation (hereinafter, also referred to as distilled off) is analyzed, and as a result, it is found that acetylacetone is contained in addition to pyridine and propionic acid contained in the first solvent. This indicates that acetylacetonate (a conjugate base of acetylacetone) coordinated with a rare earth element (hereinafter, also referred to as RE), barium (hereinafter, also referred to as Ba), and copper (hereinafter, also referred to as Cu) in rare earth acetylacetonate (hereinafter, also referred to as RE acetylacetonate), barium acetylacetonate (hereinafter, also referred to as Ba acetylacetonate), and copper acetylacetonate (hereinafter, also referred to as Cu acetylacetonate) which are organometallic compounds, is substituted with propionate (a conjugate base of propionic acid) derived from propionic acid and liberated as acetylacetone during the first dissolution step and the evaporation drying step in the manufacturing process of the conventional raw material solutions. Since such a ligand substitution reaction from acetylacetonate to propionate occurs, variation in the amount of the solvent distilled off in the evaporation drying step generates variation in the amount of the ligand substituted, resulting in variation in the quality of the raw material solution.

Thus, to prevent the generation of variation in the amount of the ligand substituted, the present inventors have examined to carry out the second dissolution step in the manufacturing process of the raw material solution without carrying out the first dissolution step and the evaporation drying step, that is, to set the manufacturing process of the raw material solution to only the dissolution step of the solute. Here, since each ligand of RE, Ba, and Cu of organometallic compounds in the solute is substituted with propionate which is a carbonate derived from carboxylic acid (a conjugate base of carboxylic acid) in the solvent of the conventional raw material solutions, the present inventors have attempted to solve the above problem by dissolving solutes including metal carboxylates as organometallic compounds in solvents including carboxylic acid.

### [Solute]

The raw material solution of the present embodiment contains a RE carboxylate having 1 or more and 4 or less carbon atoms, a Ba carboxylate having 1 or more and 4 or less carbon atoms, and a Cu carboxylate having 1 or more and 4 or less carbon atoms as solutes. Since the ligand of RE, Ba, and Cu of the RE carboxylate, the Ba carboxylate, and the Cu carboxylate as solutes is not acetylacetonate but carbonate, multiple steps and precise control upon preparation of the raw material solution are not required.

Each of the RE carboxylate, the Ba carboxylate, and the Cu carboxylate as solutes is a carboxylate having 1 or more and 4 or less carbon atoms. Such a carboxylate has high solubility in the solvent and dissolution stability. In addition, from the viewpoint of high solubility in the solvent and dissolution stability, the RE carboxylate, the Ba carboxylate, and the Cu carboxylate are preferably a carboxylate having 2 or more and 3 or less carbon atoms.

Examples of the RE carboxylate, the Ba carboxylate, and the Cu carboxylate as solutes include monocarboxylates and dicarboxylates, and from the viewpoint of high solubility in the solvent and dissolution stability, at least one carboxylate of the RE carboxylate, the Ba carboxylate, and the Cu carboxylate is preferably a monocarboxylate. Here, examples of the monocarboxylate having 1 or more and 4 or less carbon atoms include formate, acetate, propionate, and butylate. Examples of the dicarboxylate having 2 or more and 4 or less carbon atoms include oxalate, malonate, and succinate.

Further, from the viewpoint of high solubility in the solvent and dissolution stability, at least one carboxylate of the RE carboxylate, the Ba carboxylate, and the Cu carboxylate is more preferably a monocarboxylate having 2 or more and 3 or less carbon atoms. Here, examples of the monocarboxylate having 2 or more and 3 or less carbon atoms include acetate and propionate.

From the viewpoint of the high stability of the solution, at least one carboxylate of the RE carboxylate, the Ba carboxylate, and the Cu carboxylate as solutes is preferably a dicarboxylate having 2 or more and 4 or less carbon atoms (that is, oxalate, malonate, and/or succinate).

RE in the RE carboxylate is not limited as long as it is RE, and is not particularly limited as long as it is RE capable of manufacturing a high-quality oxide superconducting material. Suitable examples thereof include Y (yttrium), La (lanthanum), Pr (praseodymium), Nd (neodymium), Sm (samarium), Eu (europium), Gd (gadolinium), Tb (terbium), Dy (dysprosium), Ho (holmium), Er (erbium), Tm (thulium), Yb (ytterbium), and Lu (lutetium).

The molar ratio of RE, Ba, and Cu in the RE carboxylate, Ba carboxylate, and Cu carboxylate contained in the solute is suitably the stoichiometric ratio of the oxide superconducting material to be manufactured, or near the stoichiometric ratio. For example, in the RE carboxylate, Ba carboxylate, and Cu carboxylate in the raw material solution for manufacturing a REBa₂Cu₃O_{7-δ} superconducting material (hereinafter, also referred to as the RE123 superconducting material), the molar ratio of RE:Ba:Cu is preferably 1±0.1:2±0.2:3±0.3, more preferably 1±0.05:2±0.10:3±0.15, and particularly preferably 1:2:3.

From the viewpoint of manufacturing a high-quality oxide superconducting material, Cl (chlorine) is preferably added to the raw material solution. For this purpose, examples of an additional source of Cl include organic compounds such as trichloroacetic acid, hydrochloric acid, and ammonium chloride. The raw material solution to which Cl is added is calcined to form chlorides such as CuCl (melting point: 430° C.) and CuCl₂ (melting point: 498° C.) which have a melting point lower than the firing temperature. The chloride becomes a melt upon crystallization of the oxide superconductor in the firing (e.g., 800° C.) and does not inhibit the c-axis orientation of the oxide superconductor crystal. Thus, improvement of the quality such as larger critical current Ic of the oxide superconducting material is achieved. As the additional source of Cl, ammonium chloride is preferable, from the viewpoint of allowing Cl to remain on the calcined film upon firing.

### [Solvent]

The raw material solution of the present embodiment contains water, two or more types of alcohols having 1 or more and 4 or less carbon atoms, a carboxylic acid having 1 or more and 4 or less carbon atoms, and a basic organic solvent, as solvents. With such solvents, the solubility and dissolution stability of the solute are high, and the wettability of the raw material solution on the substrate is high.

### (Water)

Water enhances not only the solubility, but also dissolution stability of the solute, and in particular, enhances dissolution stability. Thus, water prevents the precipitation of the solute from the raw material solution. Water is not particularly limited, as long as the oxide superconducting material can be manufactured. Water is preferably one having a specific resistance of 1 MΩ·cm or more, such as ion-exchange water, distilled water, or RO (reverse osmosis) water.

### (Two or More Types of Alcohols Having 1 or More and 4 or Less Carbon Atoms)

Two or more types of alcohols having 1 or more and 4 or less carbon atoms enhance not only the solubility of the solute, but also enhance the wettability of the raw material solution on the substrate. Here, as the alcohol has a smaller number of carbon atoms, the solubility of the solute is higher, and as the alcohol has a larger number of carbon atoms, the wettability of the raw material solution on the substrate is higher. The two or more types of alcohols having 1 or more and 4 or less carbon atoms preferably include an alcohol having 1 or more and 2 or less carbon atoms and an alcohol having 3 or more and 4 or less carbon atoms. The alcohol having 1 or more and 2 or less carbon atoms enhances the solubility of the solute, and the alcohol having 3 or more and 4 or less carbon atoms enhances the wettability of the raw material solution on the substrate. Thus, when the solvent contains the alcohol having 1 or more and 2 or less carbon atoms and the alcohol having 3 or more and 4 or less carbon atoms as the two or more types of alcohols having 1 or more and 4 or less carbon atoms, the solubility of the solute and the wettability of the raw material solution on the substrate can be enhanced and also can be modulated. Here, examples of the alcohol having 1 or more and 2 or less carbon atoms include methanol and ethanol. Examples of the alcohol having 3 or more and 4 or less carbon atoms include 1-propanol, 2-propanol, 1-butanol, 2-butanol, isobutyl alcohol (also referred to as 2-methylpropan-1-ol or 2-methylpropyl alcohol), and tert-butyl alcohol (also referred to as 2-methyl-2-propanol).

From the viewpoint of enhancing the solubility of the solute and the wettability of the raw material solution on the substrate and enhancing the modulation of those properties, the two or more types of alcohols having 1 or more and 4 or less carbon atoms more preferably include an alcohol having 1 carbon atom and an alcohol having 4 carbon atoms, and for example, more preferably include methanol and 1-butanol or 2-butanol.

The volume ratio of the alcohol having 1 or more and 2 or less carbon atoms to the alcohol having 3 or more and 4 or less carbon atoms included in the two or more types of alcohols having 1 or more and 4 or less carbon atoms is preferably in the range of 5:1 to 1:5. By setting the volume ratio of the alcohol having 1 or more and 2 or less carbon atoms to the alcohol having 3 or more and 4 or less carbon atoms in the range of 5:1 to 1:5, the solubility of the solute and the wettability of the raw material solution on the substrate can be enhanced in a well-balanced manner. In addition, from such a viewpoint, the volume ratio of the alcohol having 1 or more and 2 or less carbon atoms to the alcohol having 3 or more and 4 or less carbon atoms is more preferably in the range of 4:1 to 1:4.

### (Carboxylic Acid Having 1 or More and 4 or Less Carbon Atoms)

The carboxylic acid having 1 or more and 4 or less carbon atoms enhances the solubility of the solute. Each of the RE carboxylate, the Ba carboxylate, and the Cu carboxylate as solutes is a carboxylate acid having 1 or more and 4 or less carbon atoms, each ligand of RE, Ba, and Cu in the dissolved solute is a carbonate having 1 or more and 4 or less carbon atoms before and after substitution, and thus the coordinated species does not change or the change is small. That is, the RE carboxylate, the Ba carboxylate, and the Cu carboxylate described above are the same carbonate, and have no difference in the number of carbon atoms, or, if any, the difference is in the range of 1 to 3. Thus, the carboxylic acid having 1 or more and 4 or less carbon atoms also enhances the dissolution stability of the solute.

From the viewpoint of enhancing the solubility and dissolution stability of the solute, the carboxylic acid having 1 or more and 4 or less carbon atoms is preferably a carboxylic acid having 2 or more and 3 or less carbon atoms. Examples of the carboxylic acid having 1 or more and 4 or less carbon atoms include monocarboxylic acid and dicarboxylic acid, and from the viewpoint of high solubility and dissolution stability of the solute, monocarboxylic acid is preferable. Here, examples of the monocarboxylic acid having 1 or more and 4 or less carbon atoms include formic acid, acetic acid, propionic acid, and butyric acid. Examples of the dicarboxylic acid having 1 or more and 4 or less carbon atoms include oxalic acid, malonic acid, and succinic acid.

Further, from the viewpoint of enhancing the solubility and dissolution stability of the solute, the carboxylic acid having 1 or more and 4 or less carbon atoms is more preferably a monocarboxylic acid having 2 or more and 3 or less carbon atoms. When the RE carboxylate, the Ba carboxylate, and the Cu carboxylate which are monocarboxylates having 2 or more and 3 or less carbon atoms as solutes are dissolved in a solvent containing a carboxylic acid which is the monocarboxylic acid having 2 or more and 3 or less carbon atoms, each ligand of RE, Ba, and Cu in the dissolved solute is a carbonate having 2 or more and 3 or less carbon atoms before and after substitution, and thus the coordinated species does not change or the change is significantly small. That is, a combination of the solute which is a monocarboxylate having 2 or more and 3 or less carbon atoms and the solvent containing a monocarboxylic acid having 2 or more and 3 or less carbon atoms is further preferable, because they are the same monocarbonate, and have no difference in the number of carbon atoms, or, if any, the difference is 1.

### (Basic Organic Solvent)

The basic organic solvent enhances the solubility of the solute. In addition, the basic organic solvent neutralizes the carboxylic acid having 1 or more and 4 or less carbon atoms. The basic organic solvent is not particularly limited, as long as it has compatibility with other solvents and neutralizes the carboxylic acid having 1 or more and 4 or less carbon atoms. The pKa of the conjugate acid of the basic organic solvent is preferably 5 or more and 14 or less, from the viewpoint of efficiently neutralizing the carboxylic acid having 1 or more and 4 or less carbon atoms (e.g., the pKa of formic acid is 3.75, the pKa of acetic acid is 4.76, the pKa of propionic acid is 4.87, the pKa of butyric acid is 4.82).

From the viewpoint of neutralizing the carboxylic acid having 1 or more and 4 or less carbon atoms, the basic organic solvent is preferably an organic compound containing a nitrogen atom. Examples of such a basic organic solvent include pyridine, the conjugate acid of which has a pKa of 5.25, and ethylenediamine, the conjugate acid of which has a pKa of 10.7.

### (Proportion of Each Component in Solvent)

From the viewpoint of enhancing the solubility of the solute, dissolution stability, and the wettability of the raw material solution on the substrate in a well-balanced manner, the proportion of each component in the solvent is preferably such that the content of water is 10% by volume or more and 30% by volume or less, the content of the two or more types of alcohols having 1 or more and 4 or less carbon atoms is 20% by volume or more 80% by volume or less, and the total content of the carboxylic acid having 1 or more and 4 or less carbon atoms and the basic organic solvent is 10% by volume or more and 50% by volume or less. In addition, the total content of the carboxylic acid having 1 or more and 4 or less carbon atoms and the basic organic solvent is more preferably 20% by volume or more and 40% by volume or less.

### [Concentration of Solute in Raw Material Solution]

The concentration of the solute in the solution in the raw material solution is not particularly limited, and is preferably 1.0 mol/l or more from the viewpoint of efficiently manufacturing a high-quality oxide superconducting material, and preferably 1.5 mol/l or less from the solubility of the solute in the raw material solution. In addition, the raw material solution may be used by being appropriately diluted with the solvent according to the application process and adjusting the concentration of the solute in the solution to 0.1 mol/l or more and 1.0 mol/l or less.

### [Method for Manufacturing Raw Material Solution]

The method for manufacturing the raw material solution of the present embodiment is not particularly limited, and from the viewpoint of eliminating the requirement of multiple steps and precise control upon preparation, a solute containing a RE carboxylate having 1 or more and 4 or less carbon atoms, a Ba carboxylate having 1 or more and 4 or less carbon atoms, and a Cu carboxylate having 1 or more and 4 or less carbon atoms is preferably dissolved in a solvent containing water, two or more types of alcohols having 1 or more and 4 or less carbon atoms, a carboxylic acid having 1 or more and 4 or less carbon atoms, and a basic organic solvent. Here, the RE carboxylate having 1 or more and 4 or less carbon atoms, the Ba carboxylate having 1 or more and 4 or less carbon atoms, the Cu carboxylate having 1 or more and 4 or less carbon atoms, the water, the two or more types of alcohols having 1 or more and 4 or less carbon atoms, the carboxylic acid having 1 or more and 4 or less carbon atoms, and the basic organic solvent are as described above, and the description thereof is not repeated.

From the viewpoint of manufacturing a high-quality oxide superconducting material, Cl (chlorine) may be added to the raw material solution. For this purpose, examples of an additional source of Cl include organic compounds such as trichloroacetic acid, hydrochloric acid, and ammonium chloride. Each of the above additional sources of Cl can be added as a solute.

### <Embodiment 2: Method for Manufacturing Oxide Superconducting Material>

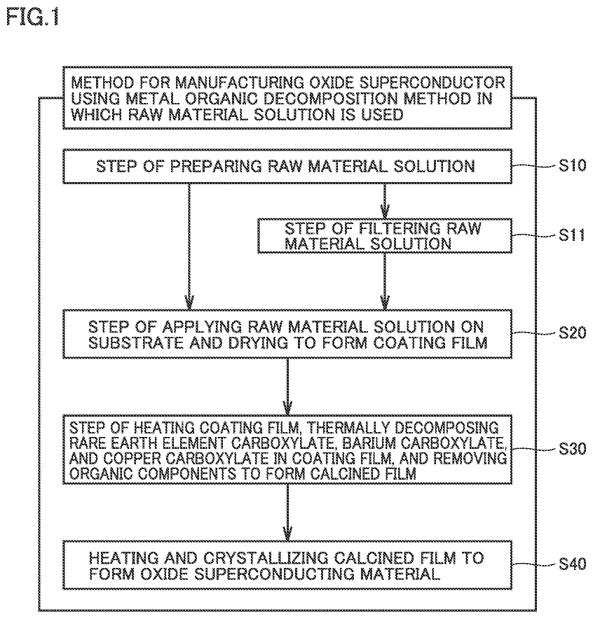

With reference to FIG. 1, the method for manufacturing an oxide superconducting material of the present embodiment is a method for manufacturing an oxide superconducting material using a metal organic decomposition method in which the raw material solution of embodiment 1 is used, and comprises a step S10 of preparing a raw material solution, a step S20 of applying the raw material solution on a substrate and drying to form a coating film, a step S30 of heating the coating film, thermally decomposing a RE carboxylate, a Ba carboxylate, and a Cu carboxylate in the coating film, and removing organic components to form a calcined film, and a step S40 of heating and crystallizing the calcined film to form an oxide superconducting material. Since the method for manufacturing an oxide superconducting material of the present embodiment uses the raw material solution of embodiment 1, a high-quality oxide superconducting material can be efficiently manufactured.

### (Step S10 of Preparing Raw Material Solution)

In the step of preparing a raw material solution, the raw material solution is prepared by preparing the raw material solution by the method for manufacturing the raw material solution of embodiment 1 or commercially obtaining the raw material solution thus prepared. Here, since the raw material solution of embodiment 1 can be prepared by only the step of dissolving predetermined solutes in predetermined solvents, the step of preparing a raw material solution requires neither multiple steps nor precise control upon preparation of the raw material solution.

### (Step S11 of Filtering Raw Material Solution)

From the viewpoint of removing insoluble impurities in the raw material solution and enhancing the quality of the oxide superconducting material, the method for manufacturing an oxide superconducting material of the present embodiment may comprise step S11 of filtering the raw material solution after the above step S10 of preparing a raw material solution and before step S20 of applying the raw material solution on a substrate and drying to form a coating film described below. The filter to be used for filtration is not particularly limited, as long as it has chemical and mechanical durability upon filtration of the raw material solution, and suitable examples thereof include a filter made of PTFE (polytetrafluoroethylene) with a pore diameter of 0.2 μm.

### (Step S20 of Applying Raw Material Solution on Substrate and Drying to Form Coating Film)

In the step of applying the raw material solution on a substrate and drying to form a coating film, the raw material solution prepared as described above, or the raw material solution prepared and filtered as described above is applied on the substrate and dried to form a coating film.

The substrate is not particularly limited, as long as it has heat resistance and mechanical strength in the heat treatment described below, and an oriented metal substrate, an IBAD (Ion Beam Assisted Deposition) substrate, or the like is preferable. The oriented metal substrate may be, for example, a clad substrate in which a copper layer, a nickel layer, and the like are laminated on a base metal substrate of SUS or hastelloy (R).

The application method is not particularly limited, as long as the raw material solution can be uniformly applied, and examples thereof include die coating, spin coating, spray coating, and inkjet coating. From the viewpoint of forming an oxide superconducting material having a suitable thickness, the thickness of the coating film is not particularly limited, and is preferably 1 μm or more and 20 μm or less per one coating. The drying method is not particularly limited, as long as the raw material solution can be uniformly dried, and examples thereof include heat drying, warm air drying, and infrared drying. The drying temperature is not particularly limited, and is preferably 100° C. or more and 250° C. or less, and more preferably 150° C. or more and 230° C. or less, from the viewpoint of sufficiently drying the solvent. When calcination in the next step is continuously carried out after application, there is no need to separately provide a drying step, as long as drying is naturally carried out during a process for raising the temperature in the calcination step.

### (Step S30 of Heating Coating Film, Thermally Decomposing RE Carboxylate, Ba Carboxylate, and Cu Carboxylate in Coating Film, and Removing Organic Components to Form Calcined Film)

From the viewpoint of forming a uniform calcined film, the heating atmosphere of the coating film in the step of forming a calcined film preferably contains 0.1 atm or more of oxygen, and further preferably contains water vapor with a dew point of 10° C. or more, as needed. The heating temperature is preferably a temperature of 450° C. or more and 600° C. or less, and more preferably a temperature of 480° C. or more and 550° C. or less.

A multilayer structure may be formed by repeating the process from step S20 of forming a coating film to step S30 of forming a calcined film multiple times, as needed, until the calcined film has a desired film thickness.

### (Step S40 of Heating and Crystallizing Calcined Film to Form Oxide Superconducting Material)

Through the step of forming an oxide superconducting material, an oxide superconducting material in a film form (hereinafter, also referred to as the oxide superconducting film) can be obtained. The thickness of the oxide superconducting film is not particularly limited, and is suitably 10 nm or more and 500 nm or less per one application, from the viewpoint of shortening the process time and preventing a crack on the calcined film. From the viewpoint of forming a high-quality oxide superconducting film, the step of forming an oxide superconducting material preferably comprises a firing step of crystallizing the calcined film to form a fired film. The heating atmosphere in the firing step is preferably low oxygen partial pressure (1 Pa or more and 500 Pa or less). The heating temperature in the firing step is preferably 700° C. or more and 900° C. or less, and more preferably 750° C. or more and 850° C. or less.

A multilayer structure may be formed by repeating the process from step S20 of forming a coating film through step S30 of forming a calcined film to the firing step of forming a fired film multiple times, as needed, until the oxide superconducting film has a desired film thickness. The final film thickness of the oxide superconducting film is preferably 10 μm or less, but may be further thick, as needed.

From the viewpoint of forming a high-quality oxide superconducting film, the step of forming an oxide superconducting material preferably further comprises an annealing step of controlling the oxygen of the fired film to form an oxide superconducting thin film. The heating atmosphere in the annealing step is preferably high oxygen partial pressure (1×10⁴ Pa or more). The heating temperature in the annealing step is preferably 150° C. or more and 600° C. or less, and more preferably 200° C. or more and 550° C. or less.

### EXAMPLES

### (Solute)

With reference to Table 1 to Table 4, each solute in which Gd propionate, Gd acetate, Gd oxalate, Y propionate, Y acetate, or Y oxalate, which are RE carboxylates; Ba propionate, Ba acetate, or Ba oxalate, which are Ba carboxylates; and Cu propionate, Cu acetate, or Cu oxalate, which are Cu carboxylates, were prepared in a molar ratio of 1:2:3 was used in Comparative Examples 1 to 3 and Examples 1 to 34.

### (Solvent)

With reference to Table 1, a solvent in which water and methanol were mixed in a volume ratio of 1:5 was used in Comparative Example 1. In Comparative Example 2, a solvent in which water, methanol, and 1-butanol were mixed in a volume ratio of 1:4:1 was used. In Comparative Example 3, a solvent in which water, methanol, 1-butanol, and propionic acid were mixed in a volume ratio of 1:4:1:1 was used. In Examples 1 to 34, each solvent in which the solvents shown in Table 1 to Table 4 were mixed in a volume ratio shown in Table 1 to Table 4 was used. The numerical value in the parenthesis described on the right side of the volume ratio in the column of the solvent in Table 1 to Table 4 is the proportion of each solvent indicated in % by volume when the total solvent is taken as 100% by volume.

### [1] Evaluation Test of Solubility of Solute of Raw Material Solution

After 0.01 mol of the above solute in total was added to the above solvent and stirred at 25° C. for 5 hours, and whether the solute was dissolved or not was evaluated. In the evaluation of the solubility, the raw material solution having a solubility of 1.0 mol/l or more (good) is preferable, and one having a solubility of 1.5 mol/l or more (excellent) is more preferable. The results are summarized in Table 1 to Table 4.

In Comparative Examples 1 and 2, the solubility of the solute was less than 1.0 mol/l and poor, whereas, in Comparative Example 3 and Examples 1 to 34, the solubility of the solute was good or excellent. As a result, it was found that, in addition to water, methanol, and 1-butanol (two types of alcohols having 1 or more and 4 or less carbon atoms), propionic acid (a carboxylic acid having 1 or more and 4 or less carbon atoms) is necessary as the solvent to enhance the solubility of the solute of the raw material solution.

### [2] Evaluation Test of Application Properties of Raw Material Solution on Substrate

The state of the coating film when a clad substrate with 220 mm in length×30 mm in width×120 um in thickness was die-coated with each raw material solution of Comparative Examples 1 to 3 and Examples 1 to 34 at a thickness of 5 um was evaluated. The substrate on which the raw material solution was repelled and no uniform coating film was obtained was evaluated as N (poor), and one on which a uniform coating film was obtained was evaluated as G (good). The results are summarized in Table 1 to Table 4.

Only in Comparative Example 1, the application properties of the raw material solution on the substrate were poor. As a result, it was found that, in addition to water and methanol (an alcohol having 1 or more and 2 or less carbon atoms), 1-butanol (an alcohol having 3 or more and 4 or less carbon atoms) is necessary as the solvent to enhance the application properties of the raw material solution on the substrate.

### [3] Evaluation Test of Dissolution Resistance of Calcined Film

A clad substrate with 220 mm in length×30 mm in width×120 um in thickness was die-coated with each raw material solution of Comparative Examples 1 to 3 and Examples 1 to 34 at a thickness of 5 μm, and then subjected to heat treatment (calcination) at 500° C. in an oxygen atmosphere humidified to a dew point of 20°° C. In Comparative Examples 2 and 3 and Examples 1 to 34, a calcined film with 150 nm in thickness was obtained. Note that, in Comparative Example 1, the application properties of the raw material solution on the substrate were poor, and therefore, no film was formed and the calcined film was not obtained. The dissolution resistance of the calcined film was evaluated by immersing each of these calcined films in the raw material solution at room temperature for 10 minutes. The calcined film whose mass reduction after the above immersion was less than 10% was evaluated as A, and the calcined film whose mass reduction after the above immersion was 10% or more was evaluated as B.

The dissolution resistance of the calcined film of Comparative Example 3,

which was slightly dissolved in the raw material solution, was poor, and the dissolution resistance of the calcined films of Comparative Example 2 and Examples 1 to 34, which were resistant to dissolution in the raw material solution, was good. Here, the reason why the dissolution resistance of the calcined film of Comparative Example 3 was poor as compared with that of Comparative Example 2 was considered to be derived from the acidity of the raw material solution of Comparative Example 3 that contains propionic acid, that is, a carboxylic acid having 1 or more and 4 or less carbon atoms. As a result, it was found that, in addition to water, methanol and 1-butanol that are two types of alcohols having 1 or more and 4 or less carbon atoms, as well as propionic acid, a basic organic solvent for neutralizing the propionic acid, such as pyridine, is necessary as the solvent to enhance the dissolution resistance of the calcined film.

### [4] Manufacture of Oxide Superconducting Material

### (1) Preparation of Raw Material Solution

With reference to Tables 1 and 2, each solute in which Gd propionate or Gd acetate, which are Gd carboxylates; Ba propionate or Ba acetate, which are Ba carboxylates; and Cu propionate or Cu acetate, which are Cu carboxylates, were prepared in a molar ratio of 1:2:3 was dissolved in each solvent in which components shown in Table 1 and Table 2 were mixed in each volume ratio. In Comparative Examples 1 and 2, a raw material solution having a concentration of the solute of 0.2 mol/l was prepared, and in Comparative Example 3 and Examples 1 to 34, a raw material solution having a concentration of the solute of 1.0 mol/l was prepared.

### (2) Filtration of Raw Material Solution

All the prepared raw material solutions of Examples and Comparative

Examples were filtered. As the filter for filtration, a filter made of PTFE (polytetrafluoroethylene) with a pore diameter of 0.2 μm (50J020AN manufactured by ADVANTEC CO., LTD. or an equivalent product) was used.

### (3) Formation of Calcined Film

A clad substrate with 5000 mm in length×30 mm in width x 120 um in thickness was die-coated with each raw material solution of Comparative Examples 1 to 3 and Examples 1 to 34 at a thickness of 5 μm, and then subjected to heat treatment (calcination) at 500° C. in an atmosphere with an oxygen partial pressure of 1 atm and a dew point of 19° C. This application and heat treatment operation was carried out multiple times. Note that, in Comparative Example 1, the application properties of the raw material solution on the substrate were poor, and therefore, no film was formed and the calcined film was not obtained.

### (4) Formation of Oxide Superconducting Material

Heat treatment (firing) in which each calcined film of Comparative Examples 2 and 3 and Examples 1 to 34 was heated at 800° C. in an argon/oxygen mixed gas (oxygen concentration: 100 ppm, CO₂ concentration: 1 ppm or less) atmosphere was carried out. Thereafter, oxygen annealing at 500° C. in an atmosphere with an oxygen concentration of 100% was carried out, and the amount of oxygen in the fired film was controlled, thereby obtaining each oxide superconducting film. In Comparative Example 1, since no calcined film was formed, no oxide superconducting material was formed. In Comparative Examples 2 and 3 and Examples 1 to 34, an oxide superconducting material with 3 μm in thickness in a film form was obtained.

### (5) Evaluation of Critical Current of Oxide Superconducting Material

The critical current Ic per 4 mm width at 77.3 K (kelvin) of each oxide 5 superconducting material of Comparative Examples 2 and 3 and Examples 1 to 34 was measured by a four-terminal method. The results are summarized in Tables 1 and 2. The oxide superconducting materials were classified into one having the critical current Ic of 200 A or less (≤200 A) and one having the critical current Ic of more than 200 A (>200 A). 200 A or less was rated as poor, and more than 200 A was rated as good.

TABLE 1

| | | Comparative | Comparative | Comparative | Example |
|---|---|---|---|---|---|
| | | Example 1 | Example 2 | Example 3 | 1 |
| Solute | Gd propionate (molar ratio) | 1 | 1 | 1 | 1 |
| | Gd acetate (molar ratio) | | | | |
| | Gd oxalate (molar ratio) | | | | |
| | Y propionate (molar ratio) | | | | |
| | Y acetate (molar ratio) | | | | |
| | Y oxalate (molar ratio) | | | | |
| | Ba propionate (molar ratio) | 2 | 2 | 2 | 2 |
| | Ba acetate (molar ratio) | | | | |
| | Ba oxalate (molar ratio) | | | | |
| | Cu propionate (molar ratio) | 3 | 3 | 3 | 3 |
| | Cu acetate (molar ratio) | | | | |
| | Cu oxalate (molar ratio) | | | | |
| Solvent | Water (volume ratio (%)) | 1(16.7) | 1(16.7) | 1(14.3) | 2(14.3) |
| | Methanol (volume ratio (%)) | 5(83.3) | 4(66.6) | 4(57.1) | 8(57.1) |
| | Ethanol (volume ratio (%)) | | | | |
| | 1-Propanol (volume ratio | | | | |
| | (%)) | | | | |
| | 2-Propanol (volume ratio | | | | |
| | (%)) | | | | |
| | 1-Butanol (volume ratio | | 1(16.7) | 1(14.3) | 2(14.3) |
| | (%)) | | | | |
| | 2-Butanol (volume ratio | | | | |
| | (%)) | | | | |
| | Propionic acid (volume | | | 1(14.3) | 1(7.15) |
| | ratio (%)) | | | | |
| | Acetic acid (volume ratio | | | | |
| | (%)) | | | | |
| | Pyridine (volume ratio | | | | 1(7.15) |
| | (%)) | | | | |
| | Ethylenediamine (volume | | | | |
| | ratio (%)) | | | | |
| Raw material | Solubility of solute (mol/l) | <1 | <1 | 1.1 | 1.1 |
| solution | Application properties | N | G | G | G |
| | on substrate | | | | |
| Calcined film | Dissolution resistance | Not formed | A | B | A |
| Oxide | Ic (A) | Not formed | >200 | ≤200 | >200 |
| superconducting | | | | | |
| material | | | | | |
| | | Example | Example | Example | Example |
| | | 2 | 3 | 4 | 5 |
| Solute | Gd propionate (molar ratio) | 1 | 1 | 1 | 1 |
| | Gd acetate (molar ratio) | | | | |
| | Gd oxalate (molar ratio) | | | | |
| | Y propionate (molar ratio) | | | | |
| | Y acetate (molar ratio) | | | | |
| | Y oxalate (molar ratio) | | | | |
| | Ba propionate (molar ratio) | 2 | 2 | 2 | 2 |
| | Ba acetate (molar ratio) | | | | |
| | Ba oxalate (molar ratio) | | | | |
| | Cu propionate (molar ratio) | 3 | 3 | 3 | 3 |
| | Cu acetate (molar ratio) | | | | |
| | Cu oxalate (molar ratio) | | | | |
| Solvent | Water (volume ratio (%)) | 1(12.5) | 2(11.1) | 1(10) | 2(9.1) |
| | Methanol (volume ratio (%)) | 4(50.0) | 8(44.4) | 4(40) | 8(36.4) |
| | Ethanol (volume ratio (%)) | | | | |
| | 1-Propanol (volume ratio | | | | |
| | (%)) | | | | |
| | 2-Propanol (volume ratio | | | | |
| | (%)) | | | | |
| | 1-Butanol (volume ratio | 1(12.5) | 2(11.1) | 1(10) | 2(9.1) |
| | (%)) | | | | |
| | 2-Butanol (volume ratio | | | | |
| | (%)) | | | | |
| | Propionic acid (volume | 1(12.5) | 3(16.7) | 2(20) | 5(22.7) |
| | ratio (%)) | | | | |
| | Acetic acid (volume ratio | | | | |
| | (%)) | | | | |
| | Pyridine (volume ratio | 1(12.5) | 3(16.7) | 2(20) | 5(22.7) |
| | (%)) | | | | |
| | Ethylenediamine (volume | | | | |
| | ratio (%)) | | | | |
| Raw material | Solubility of solute (mol/l) | 1.5 | 1.5 | 1.5 | 1.3 |
| solution | Application properties | G | G | G | G |
| | on substrate | | | | |
| Calcined film | Dissolution resistance | A | A | A | A |
| Oxide | Ic (A) | >200 | >200 | >200 | >200 |
| superconducting | | | | | |
| material | | | | | |

TABLE 2

| | | Example | Example | Example | Example |
|---|---|---|---|---|---|
| | | 6 | 7 | 8 | 9 |
| Solute | Gd propionate (molar ratio) | 1 | 1 | 1 | 1 |
| | Gd acetate (molar ratio) | | | | |
| | Gd oxalate (molar ratio) | | | | |
| | Y propionate (molar ratio) | | | | |
| | Y acetate (molar ratio) | | | | |
| | Y oxalate (molar ratio) | | | | |
| | Ba propionate (molar ratio) | 2 | 2 | 2 | 2 |
| | Ba acetate (molar ratio) | | | | |
| | Ba oxalate (molar ratio) | | | | |
| | Cu propionate (molar ratio) | 3 | 3 | 3 | 3 |
| | Cu acetate (molar ratio) | | | | |
| | Cu oxalate (molar ratio) | | | | |
| Solvent | Water (volume ratio (%)) | 2(14.3) | 1(12.5) | 2(11.1) | 1(10) |
| | Methanol (volume ratio (%)) | 2(14.3) | 1(12.5) | 2(11.1) | 1(10) |
| | Ethanol (volume ratio (%)) | | | | |
| | 1-Propanol (volume ratio | | | | |
| | (%)) | | | | |
| | 2-Propanol (volume ratio | | | | |
| | (%)) | | | | |
| | 1-Butanol (volume ratio | 8(57.1) | 4(50.0) | 8(44.4) | 4(40) |
| | (%)) | | | | |
| | 2-Butanol (volume ratio | | | | |
| | (%)) | | | | |
| | Propionic acid (volume | 1(7.15) | 1(12.5) | 3(16.7) | 2(20) |
| | ratio (%)) | | | | |
| | Acetic acid (volume ratio | | | | |
| | (%)) | | | | |
| | Pyridine (volume ratio | 1(7.15) | 1(12.5) | 3(16.7) | 2(20) |
| | (%)) | | | | |
| | Ethylenediamine (volume | | | | |
| | ratio (%)) | | | | |
| Raw material | Solubility of solute (mol/l) | 1.1 | 1.5 | 1.5 | 1.5 |
| solution | Application properties | G | G | G | G |
| | on substrate | | | | |
| Calcined film | Dissolution resistance | A | A | A | A |
| Oxide | Ic (A) | >200 | >200 | >200 | >200 |
| superconducting | | | | | |
| | | Example | Example | Example | Example |
| | | 10 | 11 | 12 | 13 |
| Solute | Gd propionate (molar ratio) | 1 | 1 | 1 | |
| | Gd acetate (molar ratio) | | | | 1 |
| | Gd oxalate (molar ratio) | | | | |
| | Y propionate (molar ratio) | | | | |
| | Y acetate (molar ratio) | | | | |
| | Y oxalate (molar ratio) | | | | |
| | Ba propionate (molar ratio) | 2 | 2 | 2 | 2 |
| | Ba acetate (molar ratio) | | | | |
| | Ba oxalate (molar ratio) | | | | |
| | Cu propionate (molar ratio) | 3 | 3 | 3 | |
| | Cu acetate (molar ratio) | | | | 3 |
| | Cu oxalate (molar ratio) | | | | |
| Solvent | Water (volume ratio (%)) | 2(9.1) | 2(20) | 2(25.0) | 2(25.0) |
| | Methanol (volume ratio (%)) | 2(9.1) | 4(40) | 2(25.0) | 2(25.0) |
| | Ethanol (volume ratio (%)) | | | | |
| | 1-Propanol (volume ratio | | | | |
| | (%)) | | | | |
| | 2-Propanol (volume ratio | | | | |
| | (%)) | | | | |
| | 1-Butanol (volume ratio | 8(36.4) | 2(20) | 2(25.0) | 2(25.0) |
| | (%)) | | | | |
| | 2-Butanol (volume ratio | | | | |
| | (%)) | | | | |
| | Propionic acid (volume | 5(22.7) | 1(10) | 1(12.5) | 1(12.5) |
| | ratio (%)) | | | | |
| | Acetic acid (volume ratio | | | | |
| | (%)) | | | | |
| | Pyridine (volume ratio | 5(22.7) | 1(10) | 1(12.5) | 1(12.5) |
| | (%)) | | | | |
| | Ethylenediamine (volume | | | | |
| | ratio (%)) | | | | |
| Raw material | Solubility of solute (mol/l) | 1.3 | 1.5 | 1.5 | 1.5 |
| solution | Application properties | G | G | G | G |
| | on substrate | | | | |
| Calcined film | Dissolution resistance | A | A | A | A |
| Oxide | Ic (A) | >200 | >200 | >200 | >200 |
| superconducting | | | | | |

| | | Example |
|---|---|---|
| | | 14 |
| Solute | Gd propionate (molar ratio) | |
| | Gd acetate (molar ratio) | 1 |
| | Gd oxalate (molar ratio) | |
| | Y propionate (molar ratio) | |
| | Y acetate (molar ratio) | |
| | Y oxalate (molar ratio) | |
| | Ba propionate (molar ratio) | |
| | Ba acetate (molar ratio) | 2 |
| | Ba oxalate (molar ratio) | |
| | Cu propionate (molar ratio) | |
| | Cu acetate (molar ratio) | 3 |
| | Cu oxalate (molar ratio) | |
| Solvent | Water (volume ratio (%)) | 2(25.0) |
| | Methanol (volume ratio (%)) | 2(25.0) |
| | Ethanol (volume ratio (%)) | |
| | 1-Propanol (volume ratio | |
| | (%)) | |
| | 2-Propanol (volume ratio | |
| | (%)) | |
| | 1-Butanol (volume ratio | 2(25.0) |
| | (%)) | |
| | 2-Butanol (volume ratio | |
| | (%)) | |
| | Propionic acid (volume | 1(12.5) |
| | ratio (%)) | |
| | Acetic acid (volume ratio | |
| | (%)) | |
| | Pyridine (volume ratio | 1(12.5) |
| | (%)) | |
| | Ethylenediamine (volume | |
| | ratio (%)) | |
| Raw material | Solubility of solute (mol/l) | 1.2 |
| solution | Application properties | G |
| | on substrate | |
| Calcined film | Dissolution resistance | A |
| Oxide | Ic (A) | >200 |
| superconducting | | |

TABLE 3

| | | Example | Example | Example | Example |
|---|---|---|---|---|---|
| | | 15 | 16 | 17 | 18 |
| Solute | Gd propionate (molar ratio) | 1 | 1 | | |
| | Gd acetate (molar ratio) | | | | |
| | Gd oxalate (molar ratio) | | | 1 | 1 |
| | Y propionate (molar ratio) | | | | |
| | Y acetate (molar ratio) | | | | |
| | Y oxalate (molar ratio) | | | | |
| | Ba propionate (molar ratio) | 2 | | 2 | 2 |
| | Ba acetate (molar ratio) | | | | |
| | Ba oxalate (molar ratio) | | 2 | | |
| | Cu propionate (molar ratio) | | 3 | 3 | |
| | Cu acetate (molar ratio) | | | | |
| | Cu oxalate (molar ratio) | 3 | | | 3 |
| Solvent | Water (volume ratio (%)) | 2(25.0) | 2(25.0) | 2(25.0) | 2(25.0) |
| | Methanol (volume ratio (%)) | 2(25.0) | 2(25.0) | 2(25.0) | 2(25.0) |
| | Ethanol (volume ratio (%)) | | | | |
| | 1-Propanol (volume ratio | | | | |
| | (%)) | | | | |
| | 2-Propanol (volume ratio | | | | |
| | (%)) | | | | |
| | 1-Butanol (volume ratio | 2(25.0) | 2(25.0) | 2(25.0) | 2(25.0) |
| | (%)) | | | | |
| | 2-Butanol (volume ratio | | | | |
| | (%)) | | | | |
| | Propionic acid (volume | 1(12.5) | 1(12.5) | 1(12.5) | 1(12.5) |
| | ratio (%)) | | | | |
| | Acetic acid (volume ratio | | | | |
| | (%)) | | | | |
| | Pyridine (volume ratio | 1(12.5) | 1(12.5) | 1(12.5) | 1(12.5) |
| | (%)) | | | | |
| | Ethylenediamine (volume | | | | |
| | ratio (%)) | | | | |
| Raw material | Solubility of solute (mol/l) | 1.2 | 1.2 | 1.2 | 1.1 |
| solution | Application properties | G | G | G | G |
| | on substrate | | | | |
| Calcined film | Dissolution resistance | A | A | A | A |
| Oxide | Ic (A) | >200 | >200 | >200 | >200 |
| superconducting | | | | | |
| | | Example | Example | Example | Example |
| | | 19 | 20 | 21 | 22 |
| Solute | Gd propionate (molar ratio) | | | | |
| | Gd acetate (molar ratio) | | | | |
| | Gd oxalate (molar ratio) | 1 | | | |
| | Y propionate (molar ratio) | | 1 | | |
| | Y acetate (molar ratio) | | | 1 | 1 |
| | Y oxalate (molar ratio) | | | | |
| | Ba propionate (molar ratio) | | 2 | 2 | |
| | Ba acetate (molar ratio) | | | | 2 |
| | Ba oxalate (molar ratio) | 2 | | | |
| | Cu propionate (molar ratio) | | 3 | | |
| | Cu acetate (molar ratio) | | | 3 | 3 |
| | Cu oxalate (molar ratio) | 3 | | | |
| Solvent | Water (volume ratio (%)) | 2(25.0) | 2(25.0) | 2(25.0) | 2(25.0) |
| | Methanol (volume ratio (%)) | 2(25.0) | 2(25.0) | 2(25.0) | 2(25.0) |
| | Ethanol (volume ratio (%)) | | | | |
| | 1-Propanol (volume ratio | | | | |
| | (%)) | | | | |
| | 2-Propanol (volume ratio | | | | |
| | (%)) | | | | |
| | 1-Butanol (volume ratio | 2(25.0) | 2(25.0) | 2(25.0) | 2(25.0) |
| | (%)) | | | | |
| | 2-Butanol (volume ratio | | | | |
| | (%)) | | | | |
| | Propionic acid (volume | 1(12.5) | 1(12.5) | 1(12.5) | 1(12.5) |
| | ratio (%)) | | | | |
| | Acetic acid (volume ratio | | | | |
| | (%)) | | | | |
| | Pyridine (volume ratio | 1(12.5) | 1(12.5) | 1(12.5) | 1(12.5) |
| | (%)) | | | | |
| | Ethylenediamine (volume | | | | |
| | ratio (%)) | | | | |
| Raw material | Solubility of solute (mol/l) | 1.1 | 1.5 | 1.5 | 1.2 |
| solution | Application properties | G | G | G | G |
| | on substrate | | | | |
| Calcined film | Dissolution resistance | A | A | A | A |
| Oxide | Ic (A) | >200 | >200 | >200 | >200 |
| superconducting | | | | | |

| | | Example | Example |
|---|---|---|---|
| | | 23 | 24 |
| Solute | Gd propionate (molar ratio) | | |
| | Gd acetate (molar ratio) | | |
| | Gd oxalate (molar ratio) | | |
| | Y propionate (molar ratio) | | |
| | Y acetate (molar ratio) | | |
| | Y oxalate (molar ratio) | 1 | 1 |
| | Ba propionate (molar ratio) | 2 | |
| | Ba acetate (molar ratio) | | |
| | Ba oxalate (molar ratio) | | 2 |
| | Cu propionate (molar ratio) | | |
| | Cu acetate (molar ratio) | | |
| | Cu oxalate (molar ratio) | 3 | 3 |
| Solvent | Water (volume ratio (%)) | 2(25.0) | 2(25.0) |
| | Methanol (volume ratio (%)) | 2(25.0) | 2(25.0) |
| | Ethanol (volume ratio (%)) | | |
| | 1-Propanol (volume ratio | | |
| | (%)) | | |
| | 2-Propanol (volume ratio | | |
| | (%)) | | |
| | 1-Butanol (volume ratio | 2(25.0) | 2(25.0) |
| | (%)) | | |
| | 2-Butanol (volume ratio | | |
| | (%)) | | |
| | Propionic acid (volume | 1(12.5) | 1(12.5) |
| | ratio (%)) | | |
| | Acetic acid (volume ratio | | |
| | (%)) | | |
| | Pyridine (volume ratio | 1(12.5) | 1(12.5) |
| | (%)) | | |
| | Ethylenediamine (volume | | |
| | ratio (%)) | | |
| Raw material | Solubility of solute (mol/l) | 1.1 | 1.1 |
| solution | Application properties | G | G |
| | on substrate | | |
| Calcined film | Dissolution resistance | A | A |
| Oxide | Ic (A) | >200 | >200 |
| superconducting | | | |

TABLE 4

| | | Example | Example | Example | Example |
|---|---|---|---|---|---|
| | | 25 | 26 | 27 | 28 |
| Solute | Gd propionate (molar ratio) | 1 | 1 | 1 | 1 |
| | Gd acetate (molar ratio) | | | | |
| | Gd oxalate (molar ratio) | | | | |
| | Y propionate (molar ratio) | | | | |
| | Y acetate (molar ratio) | | | | |
| | Y oxalate (molar ratio) | | | | |
| | Ba propionate (molar ratio) | 2 | 2 | 2 | 2 |
| | Ba acetate (molar ratio) | | | | |
| | Ba oxalate (molar ratio) | | | | |
| | Cu propionate (molar ratio) | 3 | 3 | 3 | 3 |
| | Cu acetate (molar ratio) | | | | |
| | Cu oxalate (molar ratio) | | | | |
| Solvent | Water (volume ratio (%)) | 2(25.0) | 2(25.0) | 2(25.0) | 2(25.0) |
| | Methanol (volume ratio (%)) | 2(25.0) | 2(25.0) | 2(25.0) | |
| | Ethanol (volume ratio (%)) | | | | 2(25.0) |
| | 1-Propanol (volume ratio | 2(25.0) | | | 2(25.0) |
| | (%)) | | | | |
| | 2-Propanol (volume ratio | | 2(25.0) | | |
| | (%)) | | | | |
| | 1-Butanol (volume ratio | | | | |
| | (%)) | | | | |
| | 2-Butanol (volume ratio | | | 2(25.0) | |
| | (%)) | | | | |
| | Propionic acid (volume | 1(12.5) | 1(12.5) | 1(12.5) | 1(12.5) |
| | ratio (%)) | | | | |
| | Acetic acid (volume ratio | 1(12.5) | 1(12.5) | 1(12.5) | 1(12.5) |
| | (%)) | | | | |
| | Pyridine (volume ratio | | | | |
| | (%)) | | | | |
| | Ethylenediamine (volume | | | | |
| | ratio (%)) | 1.4 | 1.4 | 1.4 | 1.3 |
| Raw material | Solubility of solute (mol/l) | G | G | G | G |
| solution | Application properties | | | | |
| | on substrate | A | A | A | A |
| Calcined film | Dissolution resistance | >200 | >200 | >200 | >200 |
| Oxide | Ic (A) | | | | |
| | | Example | Example | Example | Example |
| | | 29 | 30 | 31 | 32 |
| Solute | Gd propionate (molar ratio) | 1 | 1 | 1 | 1 |
| | Gd acetate (molar ratio) | | | | |
| | Gd oxalate (molar ratio) | | | | |
| | Y propionate (molar ratio) | | | | |
| | Y acetate (molar ratio) | | | | |
| | Y oxalate (molar ratio) | | | | |
| | Ba propionate (molar ratio) | 2 | 2 | 2 | 2 |
| | Ba acetate (molar ratio) | | | | |
| | Ba oxalate (molar ratio) | | | | |
| | Cu propionate (molar ratio) | 3 | 3 | 3 | 3 |
| | Cu acetate (molar ratio) | | | | |
| | Cu oxalate (molar ratio) | | | | |
| Solvent | Water (volume ratio (%)) | 2(25.0) | 2(25.0) | 2(25.0) | 2(25.0) |
| | Methanol (volume ratio (%)) | | | | 2(25.0) |
| | Ethanol (volume ratio (%)) | 2(25.0) | 2(25.0) | 2(25.0) | |
| | 1-Propanol (volume ratio | | | | |
| | (%)) | | | | |
| | 2-Propanol (volume ratio | 2(25.0) | | | |
| | (%)) | | | | |
| | 1-Butanol (volume ratio | | 2(25.0) | | 2(25.0) |
| | (%)) | | | | |
| | 2-Butanol (volume ratio | | | 2(25.0) | |
| | (%)) | | | | |
| | Propionic acid (volume | 1(12.5) | 1(12.5) | 1(12.5) | |
| | ratio (%)) | | | | 1(12.5) |
| | Acetic acid (volume ratio | 1(12.5) | 1(12.5) | 1(12.5) | 1(12.5) |
| | (%)) | | | | |
| | Pyridine (volume ratio | | | | |
| | (%)) | | | | |
| | Ethylenediamine (volume | | | | |
| | ratio (%)) | 1.3 | 1.3 | 1.3 | 1.3 |
| Raw material | Solubility of solute (mol/l) | G | G | G | G |
| solution | Application properties | | | | |
| | on substrate | A | A | A | A |
| Calcined film | Dissolution resistance | >200 | >200 | >200 | >200 |
| Oxide | Ic (A) | | | | |

| | | Example | Example |
|---|---|---|---|
| | | 33 | 34 |
| Solute | Gd propionate (molar ratio) | 1 | 1 |
| | Gd acetate (molar ratio) | | |
| | Gd oxalate (molar ratio) | | |
| | Y propionate (molar ratio) | | |
| | Y acetate (molar ratio) | | |
| | Y oxalate (molar ratio) | | |
| | Ba propionate (molar ratio) | 2 | 2 |
| | Ba acetate (molar ratio) | | |
| | Ba oxalate (molar ratio) | | |
| | Cu propionate (molar ratio) | 3 | 3 |
| | Cu acetate (molar ratio) | | |
| | Cu oxalate (molar ratio) | | |
| Solvent | Water (volume ratio (%)) | 2(25.0) | 2(25.0) |
| | Methanol (volume ratio (%)) | 2(25.0) | 2(25.0) |
| | Ethanol (volume ratio (%)) | | |
| | 1-Propanol (volume ratio | | |
| | (%)) | | |
| | 2-Propanol (volume ratio | | |
| | (%)) | | |
| | 1-Butanol (volume ratio | 2(25.0) | 2(25.0) |
| | (%)) | | |
| | 2-Butanol (volume ratio | | |
| | (%)) | | |
| | Propionic acid (volume | 1(12.5) | |
| | ratio (%)) | | 1(12.5) |
| | Acetic acid (volume ratio | | |
| | (%)) | | |
| | Pyridine (volume ratio | 1(12.5) | 1(12.5) |
| | (%)) | | |
| | Ethylenediamine (volume | | |
| | ratio (%)) | 1.2 | 1.2 |
| Raw material | Solubility of solute (mol/l) | G | G |
| solution | Application properties | | |
| | on substrate | A | A |
| Calcined film | Dissolution resistance | >200 | >200 |
| Oxide | Ic (A) | | |

With reference to Table 1 to Table 4, as shown in Examples 1 to 34, it was found that the raw material solution used in manufacture of an oxide superconducting material using a metal organic decomposition method, wherein the raw material solution contains a RE carboxylate having 1 or more and 4 or less carbon atoms, a Ba carboxylate having 1 or more and 4 or less carbon atoms, and a Cu carboxylate having 1 or more and 4 or less carbon atoms, as solutes, and contains water, two or more types of alcohols having 1 or more and 4 or less carbon atoms, a carboxylic acid having 1 or more and 4 or less carbon atoms, and a basic organic solvent, as solvents, has high solubility of the solute, dissolution stability, and wettability on the substrate, and thus, requires neither multiple steps nor precise control upon preparation, can be efficiently manufactured, and enables a high-quality oxide superconducting material to be efficiently manufactured.

It was also found that a method for manufacturing an oxide superconducting material using a metal organic decomposition method in which the above raw material solution is used, the method comprising a step of preparing the above raw material solution, a step of applying the above raw material solution on a substrate and drying to form a coating film, a step of heating the above coating film, thermally decomposing the above RE carboxylate, the above Ba carboxylate, and the above Cu carboxylate in the above coating film, and removing organic components to form a calcined film, and a step of heating and crystallizing the above calcined film to form an oxide superconducting material enables a high-quality oxide superconducting material to be efficiently manufactured by using the above raw material solution.

The embodiments and Examples disclosed herein should be considered to be exemplary in all respects and not restrictive. The scope of the present invention is shown by the scope of claims rather than the embodiments described above, and is intended to include the meaning equivalent to the scope of claims and all modifications within the scope.

### REFERENCE SIGNS LIST

S10 step of preparing a raw material solution; S11 step of filtering the raw material solution; S20 step of applying the raw material solution on a substrate and drying to form a coating film; S30 step of heating the coating film, thermally decomposing a rare earth element carboxylate, a barium carboxylate, and a copper carboxylate in the coating film, and removing organic components to form a calcined film; S40 step of heating and crystallizing the calcined film to form an oxide superconducting material.

1. A raw material solution used in manufacture of an oxide superconducting material using a metal organic decomposition method, wherein the raw material solution comprises:
a rare earth element carboxylate having 1 or more and 4 or less carbon atoms, a barium carboxylate having 1 or more and 4 or less carbon atoms, and a copper carboxylate having 1 or more and 4 or less carbon atoms, as solutes; and
water, two or more types of alcohols having 1 or more and 4 or less carbon atoms, a carboxylic acid having 1 or more and 4 or less carbon atoms, and a basic organic solvent, as solvents.

2. The raw material solution according to claim 1, wherein at least one carboxylate of the rare earth element carboxylate, the barium carboxylate, and the copper carboxylate is a monocarboxylate having 2 or more and 3 or less carbon atoms.

3. The raw material solution according to claim 1, wherein at least one carboxylate of the rare earth element carboxylate, the barium carboxylate, and the copper carboxylate is a dicarboxylate having 2 or more and 4 or less carbon atoms.

4. The raw material solution according to claim 1, wherein the alcohol comprises an alcohol having 1 or more and 2 or less carbon atoms and an alcohol having 3 or more and 4 or less carbon atoms.

5. The raw material solution according to claim 4, wherein a volume ratio of the alcohol having 1 or more and 2 or less carbon atoms to the alcohol having 3 or more and 4 or less carbon atoms is in a range of 5:1 to 1:5.

6. The raw material solution according to claim 1, wherein the carboxylic acid is a monocarboxylic acid having 2 or more and 3 or less carbon atoms.

7. The raw material solution according to claim 1, wherein the basic organic solvent is an organic compound containing a nitrogen atom.

8. The raw material solution according to claim 1, wherein, in the solvent, a content of the water is 10% by volume or more and 30% by volume or less, a content of the alcohol is 20% by volume or more and 80% by volume or less, and a total content of the carboxylic acid and the basic organic solvent is 10% by volume or more and 50% by volume or less.

9. A method for manufacturing an oxide superconducting material comprising:
preparing the raw material solution according to claim 1;
applying the raw material solution on a substrate and drying to form a coating film;
heating the coating film, thermally decomposing the rare earth element carboxylate, the barium carboxylate, and the copper carboxylate in the coating film, and removing organic components to form a calcined film; and
heating and crystallizing the calcined film to form an oxide superconducting material.

10. The method for manufacturing an oxide superconducting material according to claim 9, further comprising filtering the raw material solution after preparing the raw material solution and before forming the coating film.
